(19) United States
(12) Patent Application Publication
(10) Pub. No.: US 2025/0151265 A1
(43) Pub. Date: May 8, 2025

(54) INTEGRATED CIRCUIT DEVICE AND METHOD OF MANUFACTURING THE SAME

(71) Applicant: Samsung Electronics Co., Ltd., Suwon-si (KR)

(72) Inventors: Jongman Park, Suwon-si (KR); Sungho Jang, Suwon-si (KR); Seungho Hong, Suwon-si (KR); Jeonghoon Oh, Suwon-si (KR)

(21) Appl. No.: 18/740,568

(22) Filed: Jun. 12, 2024

(30) Foreign Application Priority Data
Nov. 2, 2023 (KR) 10-2023-0150285

(51) Int. Cl. H10B 12/00

(52) U.S. Cl. CPC H10B 12/50; H10B 12/315

(57) ABSTRACT

An integrated circuit device includes gate structures arranged on an upper surface of a substrate, a first impurity region arranged at the upper surface of the substrate, wherein the first impurity region is adjacent to a first gate structure of the gate structures, a first contact pad arranged on the upper surface of the substrate, wherein the first contact pad comprises a recess recessed in a vertical direction perpendicular to the upper surface of the substrate from an upper surface of the first contact pad toward the upper surface of the substrate, a metal silicide layer disposed in the recess, and a contact via connected to the metal silicide layer and extending in the vertical direction. A lower end of the contact via is disposed in the recess and connected to the metal silicide layer. The contact via is spaced apart from the substrate in the vertical direction.

### CROSS-REFERENCE TO RELATED APPLICATION

This application is based on and claims priority under 35 U.S.C. § 119 to Korean Patent Application No. 10-2023-0150285, filed on Nov. 2, 2023, in the Korean Intellectual Property Office, the disclosure of which is incorporated by reference herein in its entirety.

### BACKGROUND

The present disclosure relates to an integrated circuit device and a method of manufacturing the same, and more particularly, to an integrated circuit device including a contact pad and a method of manufacturing the integrated circuit device.

As integrated circuit devices have undergone downsizing, the size of an individual microcircuit pattern for implementing these devices has further reduced. Consequently, the short channel effect (SCE) such as drain induced barrier lowering (DIBL) has become more pronounced. In particular, the size and the depth of source/drains of a transistor have also reduced, and thus the difficulty of doping the source/drains with ions has increased.

### SUMMARY

The present disclosure provides an integrated circuit device with improved electrical characteristics and a method of manufacturing the same.

The present disclosure provides an integrated circuit device with improved reliability and a method of manufacturing the same.

The present disclosure provides a method of manufacturing an integrated circuit device with reduced difficulty in a manufacturing process.

Objectives of the disclosure are not limited to the objectives mentioned above, and other objectives not mentioned will be clearly understood by one of ordinary in the art from the description of the claims.

According to an aspect of the present disclosure, an integrated circuit device includes a plurality of gate structures arranged on an upper surface of a substrate, wherein each of the plurality of gate structures includes a gate insulating film, a gate electrode, and a gate capping layer, a first impurity region arranged at the upper surface of the substrate, wherein the first impurity region is adjacent to a first gate structure of the plurality of gate structures, a first contact pad arranged on the upper surface of the substrate, wherein the first contact pad comprises a recess recessed in a vertical direction perpendicular to the upper surface of the substrate from an upper surface of the first contact pad toward the upper surface of the substrate, a metal silicide layer disposed in the recess, and a contact via connected to the metal silicide layer and extending in the vertical direction. A lower end of the contact via is disposed in the recess and connected to the metal silicide layer. The contact via is spaced apart from the substrate in the vertical direction.

According to an aspect of the present disclosure, an integrated circuit device includes a substrate having a cell array area and a core-peripheral circuit area next to the cell array area, wherein the substrate comprises a first active area at the cell array area and a second active area at the core-peripheral circuit area, a device isolation film defining the first active area and the second active area, a plurality of bit lines disposed on the first active area and spaced apart from each other in a first horizontal direction parallel to an upper surface of the substrate, wherein each of the plurality of bit lines extends in a second horizontal direction parallel to the upper surface of the substrate and different from the first horizontal direction, a conductive plug arranged in a space between two adjacent bit lines, a landing pad disposed on the conductive plug, a peripheral circuit gate structure disposed on the second active area, an impurity region arranged at the second active area and adjacent to the peripheral circuit gate structure, a contact pad arranged on the impurity region, wherein the contact pad comprises a recess formed at an upper surface of the contact pad and recessed in a vertical direction perpendicular to the upper surface of the substrate from the upper surface of the contact pad toward the upper surface of the substrate, and a contact via connected to the contact pad and extending in the vertical direction. The contact via is spaced apart from the substrate in the vertical direction.

According to an aspect of the present disclosure, an integrated circuit device includes a substrate having a cell array area and a core-peripheral circuit area next to the cell array area, wherein the substrate comprises a first active area at the cell array area and a second active area at the core-peripheral circuit area, a device isolation film defining the first active area and the second active area, a plurality of buried gate structures buried in the cell array area of the substrate and extending in a first horizontal direction parallel to an upper surface of the substrate, wherein each of the plurality of buried gate structures comprises a buried gate electrode, a capping insulating film on the buried gate electrode, and a gate dielectric film surrounding the buried gate electrode and the capping insulating film, a plurality of bit lines disposed on the first active area and spaced apart from each other in the first horizontal direction, wherein each of the plurality of bit lines extends in a second horizontal direction parallel to the upper surface of the substrate and different from the first horizontal direction, a plurality of insulating capping structures respectively arranged on the plurality of bit lines, a conductive plug arranged in a space between two adjacent bit lines of the plurality of bit lines, a landing pad disposed on the conductive plug, a peripheral circuit gate structure disposed on the second active area and comprising a buffer film, a lower conductive pattern, a middle conductive pattern, an electrode pattern, and a gate capping pattern, which are sequentially stacked on the second active area, an insulating spacer covering a sidewall of the peripheral circuit gate structure, an impurity region arranged at the second active area to be next to the peripheral circuit gate structure, a contact pad arranged on the impurity region, wherein the contact pad comprises a recess recessed in a vertical direction perpendicular to the upper surface of the substrate from an upper surface of the contact pad toward the upper surface of the substrate, and a contact via connected to the contact pad and extending in the vertical direction. The contact via is spaced apart from the substrate in the vertical direction. A lower surface of the contact pad is coplanar with the upper surface of the substrate. The upper surface of the contact pad is lower than an upper surface of the peripheral circuit gate structure.

### BRIEF DESCRIPTION OF THE DRAWINGS

Embodiments of the present disclosure will be more clearly understood from the following detailed description taken in conjunction with the accompanying drawings in which:

FIG. 1 is a plan view of an integrated circuit device according to embodiments;

FIG. 2 is a cross-sectional view of the integrated circuit device taken along a line I-I′ of FIG. 1;

FIGS. 3A to 3C are enlarged views of a portion PP of FIG. 2;

FIGS. 4 to 12 are cross-sectional views illustrating a method of manufacturing an integrated circuit device in a process order according to embodiments;

FIG. 13 is a layout diagram showing an integrated circuit device according to embodiments;

FIG. 14 shows cross-sectional views of the integrated circuit device respectively taken along lines A1-A1′ and A2-A2′ of FIG. 13; and

FIG. 15 is a cross-sectional view of the integrated circuit device taken along a line B-B′ of FIG. 13.

### DETAILED DESCRIPTION OF THE EMBODIMENTS

Hereinafter, the present disclosure will be described in detail with reference to the attached drawings.

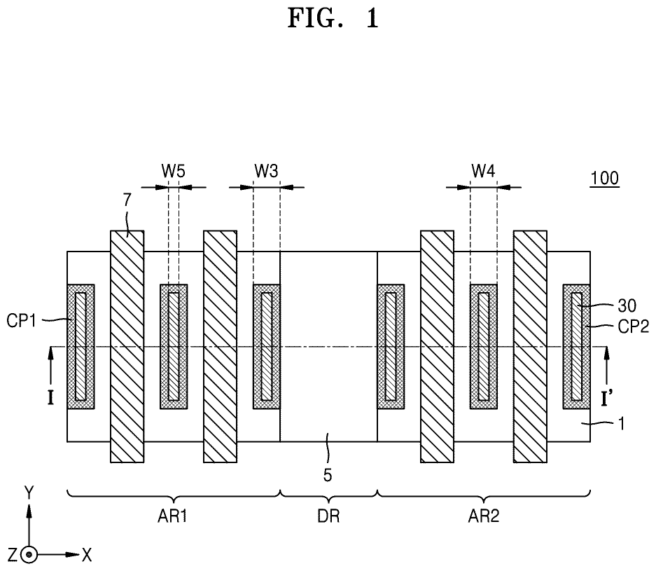

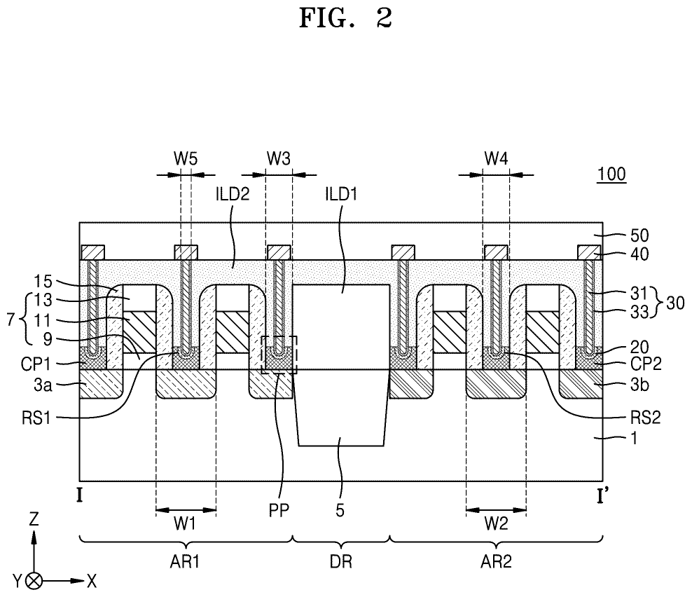

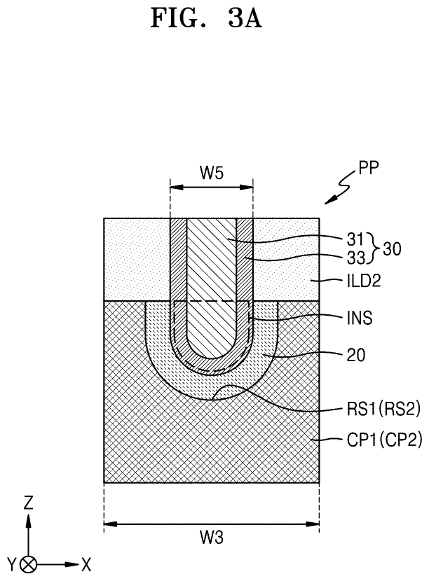

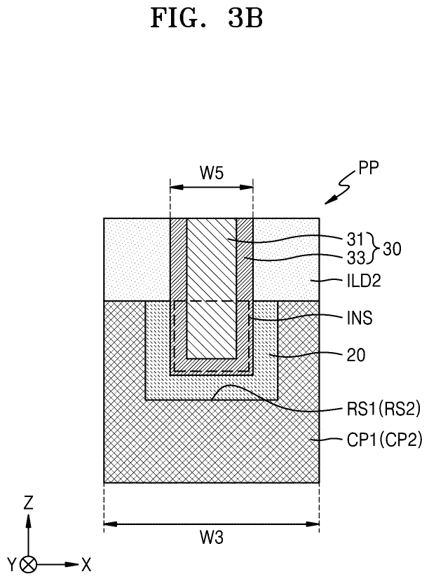

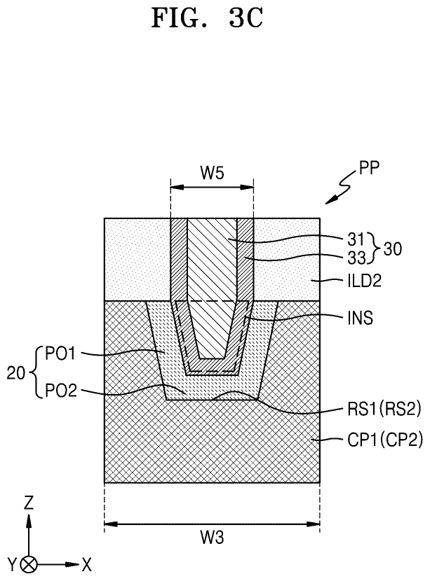

FIG. 1 is a plan view of an integrated circuit device according to embodiments. FIG. 2 is a cross-sectional view of the integrated circuit device taken along a line I-I′ of FIG. 1. FIGS. 3A to 3C are enlarged views of a portion PP of FIG. 2.

Referring to FIGS. 1 and 2, an integrated circuit device 100 may include a substrate 1, a first impurity region 3a, a second impurity region 3b, a gate stack 7 (i.e., a gate structure), a first contact pad CP1, a second contact pad CP2, a metal silicide layer 20, and a contact via 30.

The integrated circuit device 100 may be a device including a plurality of transistors. The integrated circuit device 100 may include, for example, dynamic random access memory (DRAM), NAND flash, or logic products. However, the present disclosure is not limited thereto, and the integrated circuit device 100 may be any electronic product in which a plurality of transistors form a certain circuit.

The substrate 1 may include or may be, for example, a semiconductor substrate. The substrate 1 may include or may be formed of a material containing silicon. The substrate 1 may include or may be formed of silicon, single crystal silicon, polycrystalline silicon, amorphous silicon, silicon germanium, single crystal silicon germanium, carbon-doped silicon, a combination thereof, or a multi-layer thereof. The substrate 1 may also include other semiconductor materials such as germanium. In an embodiment, the substrate 1 may include or may be formed of a group III/B compound semiconductor substrate, such as gallium arsenide (GaAs). In an embodiment, the substrate 1 may include or may be formed of a silicon-on-insulator (SOI) substrate.

The substrate 1 may include a first region AR1, a second region AR2, and a division region DR. The first region AR1 may be, for example, a region in which an N-channel metal-oxide semiconductor field effect transistor (NMOSFET) is arranged. The second region AR2 may be, for example, a region in which a P-channel metal-oxide semiconductor field effect transistor (PMOSFET) is arranged. The division region DR may be arranged in a space between the first region AR1 and the second region AR2. The first region AR1 and the second region AR2 may be spaced apart from each other in a first horizontal direction X with the division region DR therebetween.

In FIGS. 1 to 12, the first horizontal direction X is defined as one direction parallel to an upper surface of the substrate 1, a second horizontal direction Y is defined as one direction parallel to the upper surface of the substrate 1 and crossing the first horizontal direction X, and a vertical direction Z is defined as a direction perpendicular to the upper surface of the substrate 1. In an embodiment, the first horizontal direction X may be perpendicular to the second horizontal direction Y.

The first impurity region 3a and the second impurity region 3b may be disposed in the substrate 1. The first impurity region 3a and the second impurity region 3b may be regions of the substrate 1, which are doped with impurities. For example, each of the first impurity region 3a and the second impurity region 3b may be formed at an upper surface of the substrate 1, extending into the substrate 1. The impurities may include boron (B), phosphorus (P), arsenic (As), or the like. The first impurity region 3a and the second impurity region 3b may be portions which serve as source/drain regions of transistors. For example, the first impurity region 3a may include an impurity of a first conductivity type, and the second impurity region 3b may include an impurity of a second conductivity type. The first conductivity type may be different from the second conductivity type. The first conductivity type may be, for example, N-type. The second conductivity type may be, for example, P-type. When the first impurity region 3a includes or is doped with the impurity of the first conductivity type, the substrate 1 may include the impurity of the second conductivity type in the first region AR1. Similarly, when the second impurity region 3b includes or is doped with the impurity of the second conductivity type, the substrate 1 may include the impurity of the first conductivity type in the second region AR2. A plurality of first impurity regions 3a and a plurality of second impurity regions 3b may be provided.

A width of the first impurity region 3a in the first horizontal direction X may be a first width W1. A width of the second impurity region 3b in the first horizontal direction X may be a second width W2. The first width W1 and the second width W2 may be substantially the same or may be different. The first impurity region 3a with the first width W1 and the second impurity region 3b with the second width W2 may extend in the second horizontal direction Y, but the present disclosure is not limited thereto.

In the division region DR, a division structure 5 may be arranged in an upper portion of the substrate 1. The division structure 5 may be inserted into the substrate 1 from the upper surface of the substrate 1. The division structure 5 may extend in the second horizontal direction Y, but is not limited thereto. The division structure 5 may electrically insulate the first region AR1 and the second region AR2 from each other. The division structure 5 may include or may be formed of an insulating material such as silicon oxide.

The gate stack 7 may be arranged in the first region AR1 and the second region AR2. A plurality of gate stacks 7 (i.e., a plurality of gate structures) may be provided. The gate stack 7 may be arranged between a pair of first impurity regions 3a adjacent to each other in the first horizontal direction X. Another gate stack may be arranged between a pair of second impurity regions 3b adjacent to each other in the first horizontal direction X. The plurality of gate stacks 7 may be spaced apart from each other in the first horizontal direction X. The gate stack 7 may extend in the second horizontal direction Y.

The gate stack 7 may include a gate insulating layer 9, a gate electrode 11, and a gate capping layer 13, which are sequentially stacked. Each of the gate insulating layer 9, the gate electrode 11, and the gate capping layer 13 may have a single-layered structure or a multi-layered structure. For example, the gate insulating layer 9 may include or may be formed of silicon oxide, silicon nitride, silicon oxynitride, a high dielectric material, or a combination thereof. The gate electrode 11 may be a material containing silicon, a material containing metal, or a combination thereof. For example, the gate electrode 11 may include or may be formed of tungsten, titanium nitride, or a combination thereof. The gate electrode 11 may include a metal material having a work function. The gate electrode 11 may have a first-conductivity-type work function or a second-conductivity-type work function. In the first region AR1, the gate electrode 11 may have the first-conductivity-type work function. In the second region AR2, the gate electrode 11 may have the second-conductivity-type work function. The gate capping layer 13 may include or may be formed of an insulating material. The gate capping layer 13 may include or may be formed of silicon oxide, silicon nitride, or a combination thereof.

A gate spacer 15 may be arranged on each of opposite sidewalls of the gate stack 7. The gate spacer 15 may include or may be formed of an insulating material. The gate spacer 15 may have a single-layered structure or a multi-layered structure. The gate spacer 15 may include or may be formed of silicon oxide, silicon nitride, or a combination thereof.

The first contact pad CP1 and the second contact pad CP2 may be arranged on the substrate 1. The first contact pad CP1 may be arranged on the first impurity region 3a in the first region AR1 of the substrate 1. In an embodiment, the first contact pad CP1 may contact the first impurity region 3a. A plurality of first contact pads CP1 may be provided. The first contact pad CP1 may vertically overlap the first impurity region 3a. When viewed in a plan view, the first contact pad CP1 may overlap the first impurity region 3a. The second contact pad CP2 may be arranged on the second impurity region 3b in the second region AR2 of the substrate 1. In an embodiment, the second contact pad CP2 may contact the second impurity region 3b. A plurality of second contact pads CP2 may be provided. The second contact pad CP2 may vertically overlap the second impurity region 3b. For example, when viewed in a plan view, the second contact pad CP2 may overlap the second impurity region 3b. A vertical level of lower surfaces of the first contact pad CP1 and the second contact pad CP2 may be the same as a vertical level of the upper surface of the substrate 1. For example, the upper surface of the substrate 1 may be coplanar with the lower surfaces of the first and second contact pads CP1 and CP2. A vertical level of upper surfaces of the first contact pad CP1 and the second contact pad CP2 may be lower than a vertical level of an upper surface of the gate stack 7. For example, the upper surfaces of the first and second contact pads CP1 and CP2 may be lower than the upper surface of the gate stack 7. The term “contact,” as used herein, refers to a direct connection (i.e., physical touching) unless the context indicates otherwise.

The first contact pad CP1 may vertically overlap the first impurity region 3a. The first contact pad CP1 may be electrically connected to the first impurity region 3a. The second contact pad CP2 may vertically overlap the second impurity region 3b. The second contact pad CP2 may be electrically connected to the second impurity region 3b.

The first contact pad CP1 may be arranged between a pair of neighboring gate stacks 7 in the first horizontal direction X. Opposite sidewalls of the first contact pad CP1 may be in contact with two gate spacers 15 of a pair of neighboring gate stacks 7 in the first horizontal direction X. The two gate spacers 15 may face each other. The second contact pad CP2 may be arranged between a pair of neighboring gate stacks 7 in the first horizontal direction X. Opposite sidewalls of the second contact pad CP2 may be in contact with two gate spacers 15 of a pair of neighboring gate stacks 7 in the first horizontal direction X. The two gate spacers 15 may face each other.

A width of the first contact pad CP1 in the first horizontal direction X may be a third width W3. A width of the second contact pad CP2 in the first horizontal direction X may be a fourth width W4. The third width W3 may be less than the first width W1. The fourth width W4 may be less than the second width W2. The first contact pad CP1 and the second contact pad CP2 may extend in the second horizontal direction Y, but the present disclosure is not limited thereto. When viewed in a plan view, the first contact pad CP1 may be arranged in the first impurity region 3a. For example, the first contact pad CP1 may overlap the first impurity region 3a. When viewed in a plan view, the second contact pad CP2 may be arranged in the second impurity region 3b. For example, the second contact pad CP2 may overlap the second impurity region 3b.

The first contact pad CP1 and the second contact pad CP2 may each include a semiconductor material. For example, the first contact pad CP1 and the second contact pad CP2 may each include a material containing silicon. The first contact pad CP1 and the second contact pad CP2 may each include or may be formed of silicon, single crystal silicon, polycrystalline silicon, amorphous silicon, silicon germanium, single crystal silicon germanium, polycrystalline silicon germanium, carbon-doped silicon, a combination thereof, or a multi-layer thereof. In an embodiment, each of the first contact pad CP1 and the second contact pad CP2 may also include other semiconductor materials such as germanium. In an embodiment, each of the first contact pad CP1 and the second contact pad CP2 may also include a group III/V compound semiconductor substrate such as gallium arsenide (GaAs).

For example, each of the first contact pad CP1 and the second contact pad CP2 may include or may be formed of the same material as the substrate 1. In an embodiment, each of the first contact pad CP1 and the second contact pad CP2 may also include a material different from that of the substrate 1. In an embodiment, each of the first contact pad CP1 and the second contact pad CP2 may be formed through selective epitaxial growth (SEG). When each of the first contact pad CP1 and the second contact pad CP2 is formed through SEG, the first contact pad CP1 and the second contact pad CP2 may include or may be formed of the same material as the substrate 1, and the first contact pad CP1 and the second contact pad CP2 may each include or may be formed of a single crystal material. In an embodiment, the first contact pad CP1 and the second contact pad CP2 may each be formed through chemical vapor deposition (CVD), low pressure CVD (LPCVD), atomic layer deposition (ALD), or a combination thereof. When each of the first contact pad CP1 and the second contact pad CP2 is formed through CVD, LPCVD, ALD, or a combination thereof, the first contact pad CP1 and the second contact pad CP2 may include or may be formed of the same material as the substrate 1 or a different material from the substrate 1. Each of the first contact pad CP1 and the second contact pad CP2 may include or may be formed of a polycrystalline material.

The first contact pad CP1 may include or may be doped with an impurity of the same conductivity type as the first impurity region 3a. The first contact pad CP1 may include the impurity of the first conductivity type. The second contact pad CP2 may include an impurity of the same conductivity type as the second impurity region 3b, and the second contact pad CP2 may include the impurity of the second conductivity type. The first contact pad CP1 may serve as a source/drain region of a transistor together with the first impurity region 3a. The second contact pad CP2 may serve as a source/drain region of a transistor together with the second impurity region 3b.

An impurity concentration of the first contact pad CP1 may be greater than an impurity concentration of the first impurity region 3a. For example, the impurity concentration of the first contact pad CP1 may be greater than the impurity concentration of the first impurity region 3a by 10 times or more. For example, the impurity concentration of the first impurity region 3a may be a concentration selected from a range of about 1×10¹⁴ atoms/cm³ to about 1×10¹⁶ atoms/cm³, and the impurity concentration of the first contact pad CP1 may be a concentration selected from a range of about 1×10¹⁵ atoms/cm³ to about 1×10¹⁹ atoms/cm³. An impurity concentration of the second contact pad CP2 may be greater than an impurity concentration of the second impurity region 3b. For example, the impurity concentration of the second contact pad CP2 may be greater than the impurity concentration of the second impurity region 3b by 10 times or more. For example, the impurity concentration of the second impurity region 3b may be a concentration selected from a range of about 1×10¹⁴ atoms/cm³ to about 1×10¹⁶ atoms/cm³, and the impurity concentration of the second contact pad CP2 may be a concentration selected from a range of about 1×10¹⁵ atoms/cm³ to about 1×10²² atoms/cm³. However, this only corresponds to the embodiment, and particular values of the impurity concentrations of the first contact pad CP1, the second contact pad CP2, the first impurity region 3a, and the second impurity region 3b may not be limited thereto. Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

According to the present disclosure, the impurity concentration of the first contact pad CP1 may be greater than the impurity concentrations of the first impurity region 3a. And the impurity concentration of the second contact pad CP2 may be greater than the impurity concentration of the second impurity region 3b. Accordingly, because a resistance of each of the first contact pad CP1 and the second contact pad CP2 may be lowered, electrical characteristics of the integrated circuit device may be improved.

In the division region DR, a first interlayer insulating film ILD1 may be arranged. A vertical level of an upper surface of the first interlayer insulating film ILD1 may be substantially the same as the vertical level of the upper surface of the gate stack 7. The vertical level of the upper surface of the first interlayer insulating film ILD1 may be substantially the same as a vertical level of an upper surface of the gate capping layer 13. For example, the upper surface of the first interlayer insulating film ILD1 may be substantially coplanar with the upper surface of the gate capping layer 13. The first interlayer insulating film ILD1 may include or may be formed of an insulating material such as silicon oxide, silicon nitride, and silicon oxynitride. Terms such as “same,” “equal,” “planar,” or “coplanar,” as used herein encompass near identicality including variations that may occur, for example, due to manufacturing processes. The term “substantially” may be used herein to emphasize this meaning, unless the context or other statements indicate otherwise.

A second interlayer insulating film ILD2 may be arranged to cover the gate stack 7. The second interlayer insulating film ILD2 may cover the upper surface of the gate stack 7. The second interlayer insulating film ILD2 may cover at least a portion of a side surface of the gate stack 7. The second interlayer insulating film ILD2 may cover at least a portion of the upper surface of the first contact pad CP1 and at least a portion of the upper surface of the second contact pad CP2. A vertical level of an upper surface of the second interlayer insulating film ILD2 may be higher than a vertical level of the upper surface of the first interlayer insulating film ILD1 and the vertical level of the upper surface of the gate stack 7. The second interlayer insulating film ILD2 may include or may be formed of an insulating material such as silicon oxide, silicon nitride, and silicon oxynitride.

The contact via 30 may be arranged to penetrate the second interlayer insulating film ILD2. A plurality of contact vias 30 may be provided. Some contact vias 30 may be connected to the first contact pad CP1, and some other contact vias 30 may be connected to the second contact pad CP2. The contact via 30 may be spaced apart from the substrate 1 in the vertical direction Z. The contact via 30 may include a first conductive pattern 31 and a second conductive pattern 33 surrounding the first conductive pattern 31. The first conductive pattern 31 may include or may be formed of metal, metal nitride, conductive polysilicon, or a combination thereof. The second conductive pattern 33 may include or may be formed of titanium, titanium nitride, or a combination thereof.

The metal silicide layer 20 may be arranged between the first contact pad CP1 and the contact via 30 and between the second contact pad CP2 and the contact via 30. The metal silicide layer 20 may be arranged on the first contact pad CP1 and the second contact pad CP2. When the metal silicide layer 20 is arranged between the first contact pad CP1 and the contact via 30, the metal silicide layer 20 may connect the first contact pad CP1 to the contact via 30. In an embodiment, the metal silicide layer 20 may be in contact with the first contact pad CP1 and the second conductive pattern 33. When the metal silicide layer 20 is arranged between the second contact pad CP2 and the contact via 30, the metal silicide layer 20 may connect the second contact pad CP2 to the contact via 30. In an embodiment, the metal silicide layer 20 may be in contact with the second contact pad CP2 and the second conductive pattern 33. The metal silicide layer 20 may include or may be formed of cobalt silicide, nickel silicide, or manganese silicide.

An upper line 40 may be arranged on the contact via 30. The upper line 40 may be electrically connected to the contact via 30. The upper line 40 may extend in the first horizontal direction X or the second horizontal direction Y. The upper line 40 may include or may be formed of a metal material such as copper, aluminum, and tungsten.

A line insulating film 50 may be arranged to cover the upper line 40 and the second interlayer insulating film ILD2. The line insulating film 50 may include or may be formed of an insulating material such as silicon oxide, silicon nitride, and silicon oxynitride.

Hereinafter, the first and second contact pads CP1 and CP2, the metal silicide layer 20, and the contact via 30 are described in detail with reference to FIGS. 1, 2, and 3A. Referring to FIGS. 1, 2, and 3A, the first contact pad CP1 may include a first recess RS1 at an upper surface of the first contact pad CP1. For example, the first recess RS1 may be dug downward in the vertical direction Z from the upper surface of the first contact pad CP1. In an embodiment, the first recess RS1 may be recessed from the upper surface of the first contact pad CP1 toward the upper surface of the substrate 1 in the vertical direction Z. Similarly, the second contact pad CP2 may include a second recess RS2 at an upper surface of the second contact pad CP2. For example, the second recess RS2 may be dug downward in the vertical direction Z from the upper surface of the second contact pad CP2. In an embodiment, the second recess RS2 may be recessed from the upper surface of the second contact pad CP2 toward the upper surface of the substrate 1 in the vertical direction Z. The first recess RS1 may not completely penetrate the first contact pad CP1. The second recess RS2 may not completely penetrate the second contact pad CP2. In a cross-sectional view, the first recess RS1 and the second recess RS2 may each have a rounded surface. In an embodiment, each of the first and second recesses RS1 and RS2 may be defined by a recessed rounded surface. In an embodiment, the first recess RS1 and the second recess RS2 may each be formed from either a dry etching process or a wet etching process.

The metal silicide layer 20 may be arranged in the first recess RS1 and the second recess RS2. The metal silicide layer 20 may cover a surface of the first recess RS1 and a surface of the second recess RS2. The metal silicide layer 20 may not fill some spaces of the first recess RS1. The metal silicide layer 20 may not fill some spaces of the second recess RS2. For example, the metal silicide layer 20 may be lined with the recessed rounded surface of each of the first and second recesses RS1 and RS2, without completely filling the first and second recesses RS1 and RS2. The metal silicide layer 20 may have a “U”-shaped cross-sectional shape. The metal silicide layer 20 may be arranged between the contact via 30 and the first contact pad CP1 and between the contact via 30 and the second contact pad CP2. A vertical level of a lowermost surface of the metal silicide layer 20 may be higher than a vertical level of a lower surface of the first contact pad CP1 and a vertical level of a lower surface of the second contact pad CP2. In an embodiment, the lowermost surface of the metal silicide layer 20 may be higher than the lower surface of each of the first and second contact pads CP1 and CP2.

The contact via 30 may include an insertion portion INS inserted into the metal silicide layer 20. For example, the insertion portion INS (i.e., a lower potion) of the contact via 30 may be inserted into each of the first and second recesses RS1 and RS2 with the metal silicide layer 20 therein. The insertion portion INS of the contact via 30 may be a portion of the contact via 30. The insertion portion INS may be a portion between the upper surface of the first contact pad CP1 and the lowermost surface of the contact via 30. The insertion portion INS may be a portion between the upper surface of the second contact pad CP2 and the lowermost surface of the contact via 30. A surface of the insertion portion INS may be rounded.

The vertical level of the lowermost surface of the contact via 30 may be lower than the vertical levels of the upper surfaces of the first contact pad CP1 and the second contact pad CP2. In an embodiment, the lowermost surface of the contact via 30 may be lower than the upper surfaces of the first and second contact pads CP1 and CP2. The vertical level of the lowermost surface of the contact via 30 may be higher than the vertical levels of the lower surfaces of the first contact pad CP1 and the second contact pad CP2. In an embodiment, the lowermost surface of the contact via 30 may be higher than the lower surfaces of the first and second contact pads CP1 and CP2. The contact via 30 may penetrate only a portion of the first contact pad CP1 and a portion of the second contact pad CP2.

The contact via 30 may extend in the vertical direction Z within the second interlayer insulating film ILD2. The contact via 30 may extend in the second horizontal direction Y. When viewed in a plan view, the contact via 30 may be arranged within (i.e., may overlap) the first contact pad CP1. When viewed in a plan view, the contact via 30 may be arranged within (i.e., may overlap) the second contact pad CP2. A width of the contact via 30 in the first horizontal direction X may be a fifth width W5. The fifth width W5 may be less than each of the third width W3 and the fourth width W4. For example, the fifth width W5 may be less than the third width W3 by a value selected from a range of about 2 nm to about 15 nm. The third width W3 may be greater than the fifth width W5 by a value selected from a range of about 2 nm to about 15 nm. For example, the fifth width W5 may be less than the fourth width W4 by a value selected from a range of about 2 nm to about 15 nm. The fourth width W4 may be greater than the fifth width W5 by a value selected from a range of about 2 nm to about 15 nm.

The metal silicide layer 20 may surround a lower portion of the contact via 30. For example, the metal silicide layer 20 may surround the insertion portion INS of the contact via 30. The metal silicide layer 20 may extend in the second horizontal direction Y along the first contact pad CP1 or the second contact pad CP2.

Hereinafter, cross-sectional shapes of the first and second contact pads CP1 and CP2, the metal silicide layer 20, and the contact via 30 are described with reference to FIGS. 3B and 3C. Descriptions already given with reference to FIGS. 1, 2, and 3A are omitted, and only differences thereof are described.

Referring to FIG. 3B, in a cross-sectional view, the first recess RS1 and the second recess RS2 may each have a straight surface. A side surface of the first recess RS1 may be parallel to the vertical direction Z. A side surface of the second recess RS2 may be parallel to the vertical direction Z. Bottom surfaces of the first recess RS1 and the second recess RS2 may be flat. Accordingly, a cross-sectional shape of the metal silicide layer 20 covering the surface of the first recess RS1 and the surface of the second recess RS2 may have a shape obtained by rotating “C” 90 degrees counterclockwise. The insertion portion INS may have a straight surface. A side surface of the insertion portion INS may be parallel to the vertical direction Z. The lowermost surface of the insertion portion INS may be flat. In an embodiment, in a cross-sectional view, the metal silicide layer 20 may be disposed in the first recess RS1 having a flat bottom surface and a side surface extending from the flat bottom surface in the vertical direction. The flat bottom surface and the side surface may correspond to a recessed surface of the first recess RS1. The metal silicide layer 20 may be lined with the recessed surface of the first recess RS1 without completely filling the first recess RS1. In an embodiment, the metal silicide layer 20 may also be disposed in the second recess RS2 having a flat bottom surface and a side surface extending from the flat bottom surface in the vertical direction. The flat bottom surface and the side surface may correspond to a recessed surface of the second recess RS2. The metal silicide layer 20 may be lined with the recessed surface of the second recess RS2 without completely filling the second recess RS2.

Referring to FIG. 3C, in a cross-sectional view, the first recess RS1 and the second recess RS2 may each have a straight surface. A side surface of the first recess RS1 may form a certain angle with the vertical direction Z. A side surface of the second recess RS2 may form a certain angle with the vertical direction Z. The certain angle may be greater than 0 degrees and less than 90 degrees. Both side surfaces of the first recess RS1 may get close to each other in the first horizontal direction X toward the downward of the vertical direction Z. Both side surfaces of the second recess RS2 may become get close to each other in the first horizontal direction X toward the downward of the vertical direction Z. The first recess RS1 and the second recess RS2 may each have a trapezoidal cross-sectional shape with a larger upper side. The metal silicide layer 20 may include a first portion PO1 covering the side surface of the first recess RS1 or the second recess RS2 and a second portion PO2 covering a bottom surface of the first recess RS1 or the second recess RS2. The first portion PO1 may extend from the second portion PO2 along the side surface of the first recess RS1 or the second recess RS2. Two first portions PO1 may be provided along both side surfaces of the first recess RS1 or the second recess RS2. The two first portions PO1 may get close to each other in the first horizontal direction X toward the downward of the vertical direction Z. A width of the insertion portion INS in the first horizontal direction X may decrease toward the downward of the vertical direction Z. The insertion portion INS may have a trapezoidal cross-sectional shape with a larger upper side.

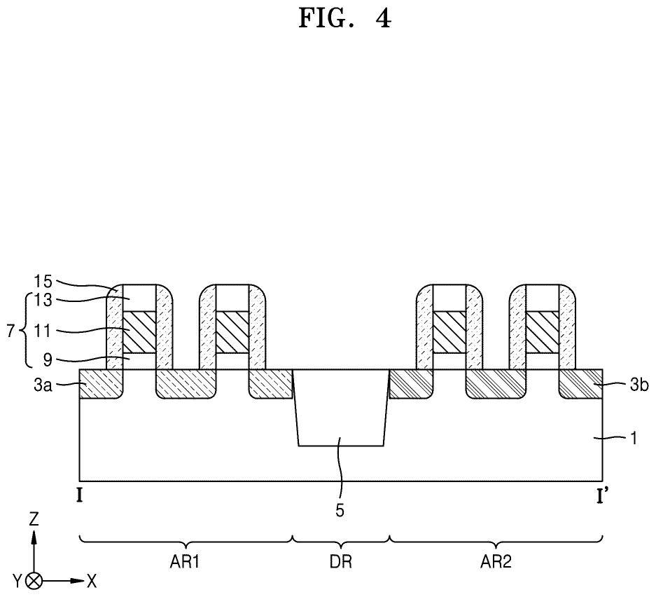

FIGS. 4 to 12 are cross-sectional views illustrating a method of manufacturing an integrated circuit device in a process order according to embodiments.

Referring to FIG. 4, the first region AR1 and the second region AR2 may be defined by forming the division structure 5 on the substrate 1. Next, in the first region AR1, the first impurity region 3a may be formed at an upper surface of the substrate 1. In the second region AR2, the second impurity region 3b may be formed at the upper surface of the substrate 1. The first impurity region 3a and the second impurity region 3b may be formed by using an ion implantation process or a thermal diffusion process. The first impurity region 3a may be doped with an impurity of the first conductivity type. The first conductivity type may be N-type. For example, the first impurity region 3a may be doped with a donor impurity such as phosphorus or arsenic. The second impurity region 3b may be doped with an impurity of the second conductivity type. The second conductivity type may be P-type. For example, the second impurity region 3b may be doped with an acceptor impurity such as boron.

The gate stack 7 may be formed on the substrate 1. The forming of the gate stack 7 may include forming a gate insulating film (not shown) on a front surface of the substrate 1, forming a gate electrode film (not shown) on the gate insulating film, forming a gate capping film (not shown) on the gate electrode film, and patterning the gate insulating film, the gate electrode film, and the gate capping film. The gate insulating layer 9, the gate electrode 11, and the gate capping layer 13 may be formed by respectively patterning the gate insulating film, the gate electrode film, and the gate capping film. In an embodiment, the gate stack 7 in the first region AR1 and the gate stack 7 in the second region AR2 may also be separately formed. This may vary depending on the design of the integrated circuit device 100 (refer to FIG. 2) to be manufactured.

The gate stack 7 may be arranged between two first impurity regions 3a adjacent to each other in the first horizontal direction X and two second impurity regions 3b adjacent to each other in the first horizontal direction X. The gate insulating layer 9 may include or may be formed of silicon oxide, silicon nitride, silicon oxynitride, a high dielectric material, or a combination thereof. The gate electrode 11 may be a material containing silicon, a material containing metal, or a combination thereof. For example, the gate electrode 11 may include or may be formed of tungsten, titanium nitride, or a combination thereof. The gate electrode 11 may include a metal material having a work function. The gate electrode 11 may have a first-conductivity-type work function or a second-conductivity-type work function. In the first region AR1, the gate electrode 11 may have the first-conductivity-type work function. In the second region AR2, the gate electrode 11 may have the second-conductivity-type work function. The gate capping layer 13 may include or may be formed of an insulating material. The gate capping layer 13 may include or may be formed of silicon oxide, silicon nitride, or a combination thereof.

The gate spacer 15 covering a side surface of the gate stack 7 may be formed. The forming of the gate spacer 15 may include forming a gate spacer film (not shown) on the front surface of substrate 1 and performing a dry etching process on the gate spacer film. While the gate spacer film deposited on the upper surface of the substrate 1 is removed in the dry etching process, the gate spacer film covering the side surface of the gate stack 7 may not be completely removed due to a difference in etch rate of dry etching on a flat surface and a vertical surface. The gate spacer 15 may be formed from the gate spacer film remaining in the dry etching process. The gate spacer 15 may have a single-layered structure or a multi-layered structure. The gate spacer 15 may include or may be formed of a silicon oxide film, a silicon nitride film, a silicon oxynitride film, or a combination thereof.

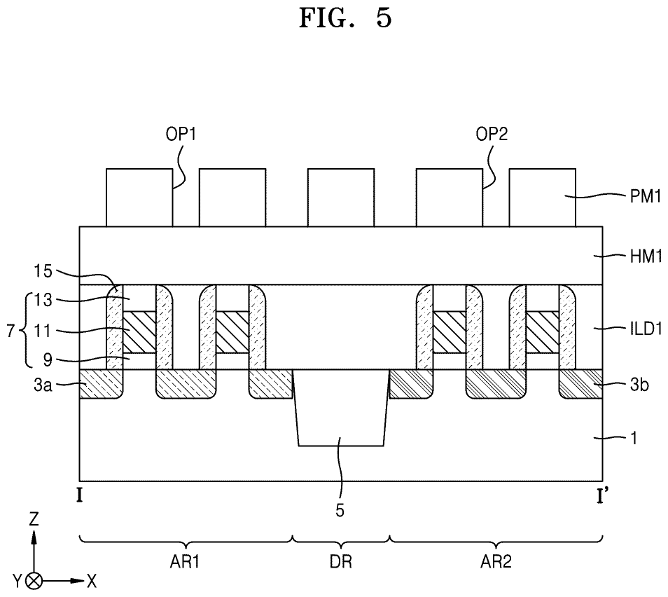

Referring to FIG. 5, the first interlayer insulating film ILD1 may be formed. The forming of the first interlayer insulating film ILD1 may include forming a material that forms the first interlayer insulating film ILD1 on the front surface of the substrate 1 and then performing a planarization process on the material. The planarization process may include a chemical mechanical polishing (CMP) process. The planarization process may be performed so that the upper surface of the gate stack 7 is exposed. In the planarization process, the vertical level of the upper surface of the first interlayer insulating film ILD1 may become substantially the same as the vertical level of the upper surface of the gate stack 7. The first interlayer insulating film ILD1 may include or may be formed of an insulating material such as a silicon oxide film, a silicon nitride film, and a silicon oxynitride film.

A first hard mask HM1 may be formed on the first interlayer insulating film ILD1. The first hard mask HM1 may include or may be formed of a spin-on-hardmask (SOH). A first photomask PM1 may be formed on the first hard mask HM1. The first photomask PM1 may include or may be formed of a photoresist material. The first photomask PM1 may include a first opening OP1 and a second opening OP2. The first opening OP1 may vertically overlap (i.e., may expose) the first impurity region 3a. The second opening OP2 may vertically overlap (i.e., may expose) the second impurity region 3b. A plurality of first openings OP1 and a plurality of second openings OP2 may be provided. A portion of an upper surface of the first hard mask HM1 may be exposed from the first opening OP1 and the second opening OP2.

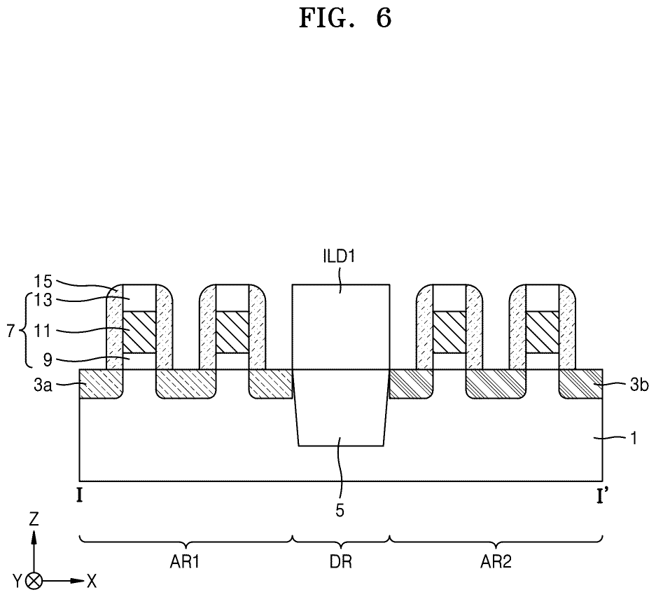

Referring to FIG. 6, an etching process may be performed on the first interlayer insulating film ILD1 by using the first photomask PM1 as an etch mask. In the etching process, a portion of the first interlayer insulating film ILD1 may be removed. Portions in which the first interlayer insulating film ILD1 is removed may be portions vertically overlapping (i.e., portions exposed by) the first opening OP1 and the second opening OP2. In the etching process, at least a portion of the upper surface of the first impurity region 3a and at least a portion of the upper surface of the second impurity region 3b may be exposed.

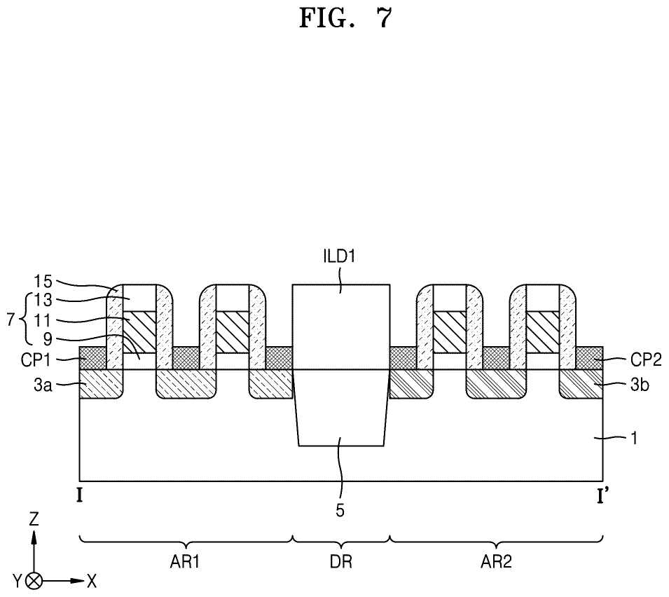

Referring to FIG. 7, the first contact pad CP1 may be formed on the first impurity region 3a, and the second contact pad CP2 may be formed on the second impurity region 3b. The first contact pad CP1 may be arranged between a pair of neighboring gate stacks 7 in the first horizontal direction X. Opposite sidewalls of the first contact pad CP1 may be in contact with two gate spacers 15 of the pair of neighboring gate stacks 7 in the first horizontal direction X, wherein the two gate spacers 15 face each other. The second contact pad CP2 may be arranged between a pair of neighboring gate stacks 7 in the first horizontal direction X. Opposite sidewalls of the second contact pad CP2 may be in contact with two gate spacers 15 of the pair of neighboring gate stacks 7 in the first horizontal direction X, wherein the two gate spacers 15 face each other.

For example, each of the first contact pad CP1 and the second contact pad CP2 may be formed through SEG. When each of the first contact pad CP1 and the second contact pad CP2 is formed through SEG, the first contact pad CP1 and the second contact pad CP2 may each include the same material as the substrate 1. At this time, the first contact pad CP1 and the second contact pad CP2 may each include a polycrystalline material. For example, the first contact pad CP1 and the second contact pad CP2 may each be formed through CVD, LPCVD, plasma enhanced CVD

(PECVD), ALD, or a combination thereof. When each of the first contact pad CP1 and the second contact pad CP2 is formed through CVD, LPCVD, PECVD, ALD, or a combination thereof, the first contact pad CP1 and the second contact pad CP2 may each include the same material as the substrate 1. At this time, each of the first contact pad CP1 and the second contact pad CP2 may include or may be formed of a polycrystalline material.

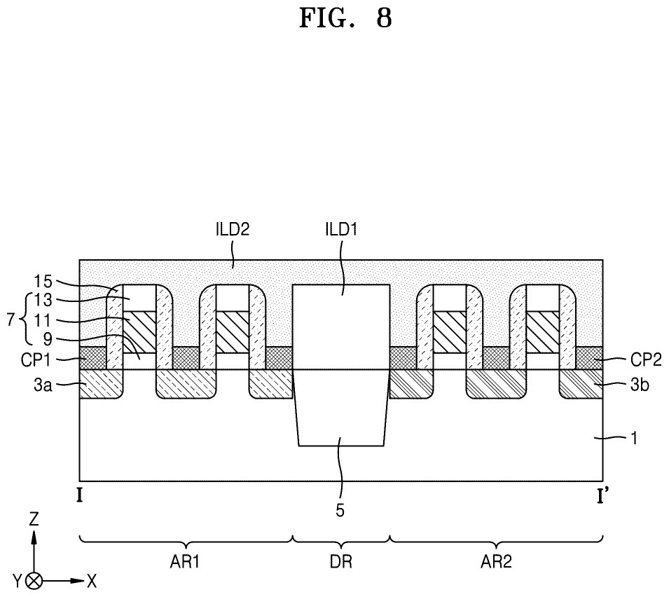

Referring to FIG. 8, the second interlayer insulating film ILD2 may be formed on the front surface of the substrate 1. The second interlayer insulating film ILD2 may cover upper and side surfaces of the gate stack 7, upper surfaces of the first and second contact pads CP1 and CP2, and upper and side surfaces of the first interlayer insulating film ILD1. The second interlayer insulating film ILD2 may include or may be formed of an insulating material such as a silicon oxide film, a silicon nitride film, and a silicon oxynitride film.

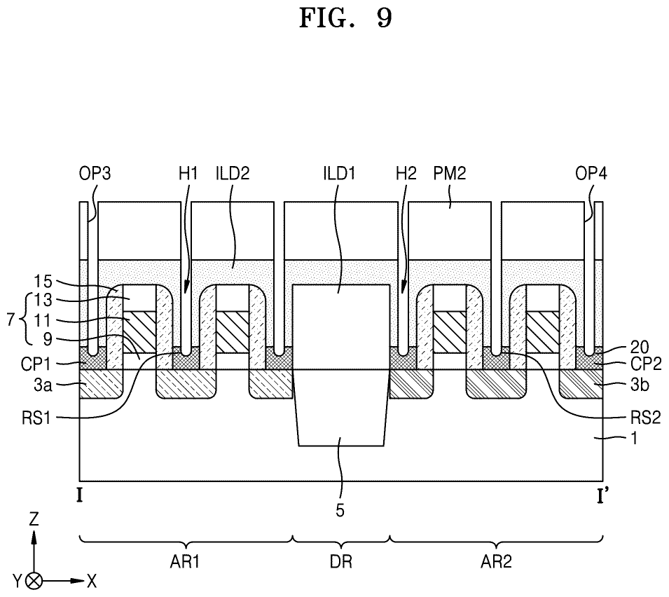

Referring to FIG. 9, a second photomask PM2 may be formed on the second interlayer insulating film ILD2. The second photomask PM2 may include a third opening OP3 and a fourth opening OP4. The third opening OP3 may vertically overlap (i.e., may expose) the first contact pad CP1, and the fourth opening OP4 may vertically overlap (i.e., may expose) the second contact pad CP2. The second photomask PM2 may include or may be formed of a photoresist material.

An etching process may be performed on the second interlayer insulating film ILD2 by using the second photomask PM2 as an etch mask. In the etching process, a first hole H1 and a second hole H2 may be formed in the second interlayer insulating film ILD2. In the etching process, a portion of the first contact pad CP1 and a portion of the second contact pad CP2 may be etched. Accordingly, the first recess RS1 may be formed in the first contact pad CP1, and the second recess RS2 may be formed in the second contact pad CP2. The first hole H1 may vertically overlap the first recess RS1. The second hole H2 may vertically overlap the second recess RS2. In an embodiment, the first hole H1 may be connected to the first recess RS1, and the second hole H2 may be connected to the second recess RS2.

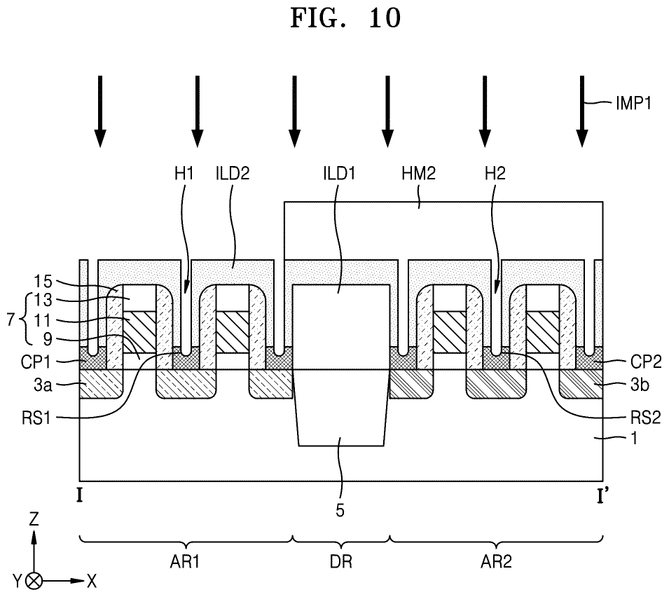

Referring to FIG. 10, the second photomask PM2 may be removed, and a second hard mask HM2 may be formed on a front surface of the second interlayer insulating film ILD2. Unlike its name, the second hard mask HM2 may include or may be formed of a photoresist material. The second hard mask HM2 may cover the second interlayer insulating film ILD2 only on the second region AR2 and the division region DR and may not be arranged on the first region AR1. Accordingly, the first contact pad CP1 may be exposed from the second hard mask HM2 and the first hole H1. The second hard mask HM2 may include or may be formed of a silicon oxide film, a photoresist material, or the like.

Next, a first impurity doping process IMP1 may be performed on the front surface of the substrate 1. An impurity used in the first impurity doping process IMP1 may have the first conductivity type. The first impurity doping process IMP1 may use an ion implantation process or a thermal diffusion process. When performing the first impurity doping process IMP1, the second region AR2 may be covered with the second hard mask HM2. Accordingly, when performing the first impurity doping process IMP1, only the first contact pad CP1 may be doped with an impurity through the first hole H1.

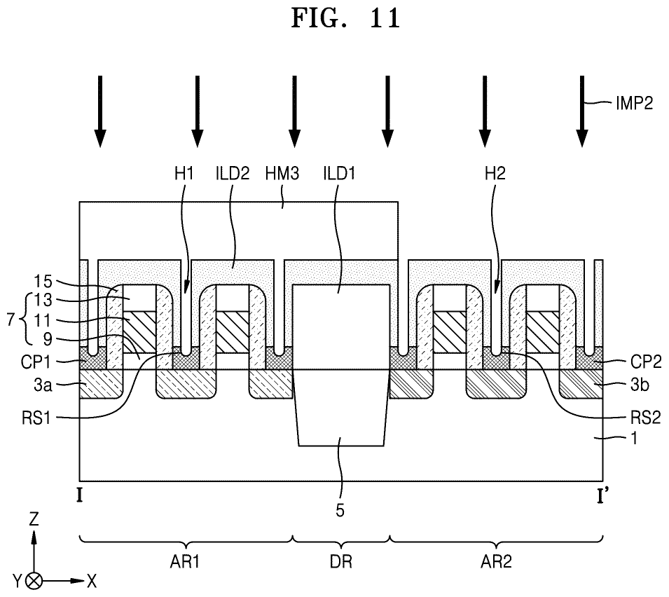

Referring to FIG. 11, the second hard mask HM2 may be removed, and a third hard mask HM3 may be formed on the front surface of the second interlayer insulating film ILD2. Unlike its name, the third hard mask HM3 may include or may be formed of a photoresist material. The third hard mask HM3 may cover the second interlayer insulating film ILD2 only on the first region AR1 and the division region DR and may not be arranged on the second region AR2. Accordingly, the second contact pad CP2 may be exposed from the third hard mask HM3 and the second hole H2. The third hard mask HM3 may include or may be formed of a silicon oxide film, a photoresist material, or the like.

Next, a second impurity doping process IMP2 may be performed on the front surface of the substrate 1. An impurity used in the second impurity doping process IMP2 may have the second conductivity type. The second impurity doping process IMP2 may use an ion implantation process or a thermal diffusion process. When performing the second impurity doping process IMP2, the first region AR1 may be covered with the third hard mask HM3. Accordingly, when performing the second impurity doping process IMP2, only the second contact pad CP2 may be doped with an impurity through the second hole H2.

As the integrated circuit device 100 has been downscaled, it is difficult to increase an impurity concentration of the first impurity region 3a and an impurity concentration of the second impurity region 3b. This is because, when increasing the impurity concentrations of the first impurity region 3a and the second impurity region 3b, a short channel effect (SCE) may occur as a depletion region is increased due to the doped impurities deeply diffusing into the substrate 1. The SCE effect may include, for example, a phenomenon such as drain induced barrier lowering (DIBL), which may degrade the reliability and electrical characteristics of the integrated circuit device 100.

According to the present disclosure, the first contact pad CP1 may be formed on the first impurity region 3a, and the second contact pad CP2 may be formed on the second impurity region 3b. The first contact pad CP1 may be doped with an impurity of the first conductivity type through the first impurity doping process IMP1, and the second contact pad CP2 may be doped with an impurity of the second conductivity type through the second impurity doping process IMP2. At this time, the impurities may be injected or diffused downward in the vertical direction Z from the upper surfaces of the first contact pad CP1 and the second contact pad CP2. Accordingly, even when concentrations of impurities doped in the first contact pad CP1 and the second contact pad CP2 are increased, the impurities may not diffuse deeply into the substrate 1. As a result, while the impurity concentrations of the first contact pad CP1, the second contact pad CP2, the first impurity region 3a, and the second impurity region 3b are increased, a depth and a horizontal width of each of the first impurity region 3a and the second impurity region 3b may be adjusted at the same time. As the impurity concentrations of the first contact pad CP1, the second contact pad CP2, the first impurity region 3a, and the second impurity region 3b are increased, a source/drain resistance of a transistor may be lowered, and in addition, a contact resistance between the contact via 30 and the first contact pad CP1 and between the contact via 30 and the second contact pad CP2 may be improved. Accordingly, an on-current in an on-state of the transistor may be improved. Also, as a depth and a horizontal width of the first impurity region 3a and the second impurity region 3b may be adjusted, an SCE such as DIBL may be avoided, thereby improving the reliability and the electrical characteristics of the integrated circuit device 100 (refer to FIG. 2).

After the gate stack 7 and the first interlayer insulating film ILD1 may be firstly formed, the first contact pad CP1 and the second contact pad CP2 may then be formed. Accordingly, the first contact pad CP1 and the second contact pad CP2 may each be formed through CVD, LPCVD, PEVCD, ALD, or a combination thereof, as well as an SEG process. That is, the number of process methods of forming the first contact pad CP1 and the second contact pad CP2 may increase, which may lead to a reduction in process difficulty and process cost.

When the third width W3, which is a horizontal width of the first contact pad CP1, and the fourth width W4, which is a horizontal width of the second contact pad CP2, is greater than the fifth width W5, which is a horizontal width of the contact via 30, an on-current may be further improved. In particular, when each of the third width W3 and the fourth width W4 is greater than the fifth width W5 by about 2 nm to about 15 nm, an effect of improving an on-current may be greater.

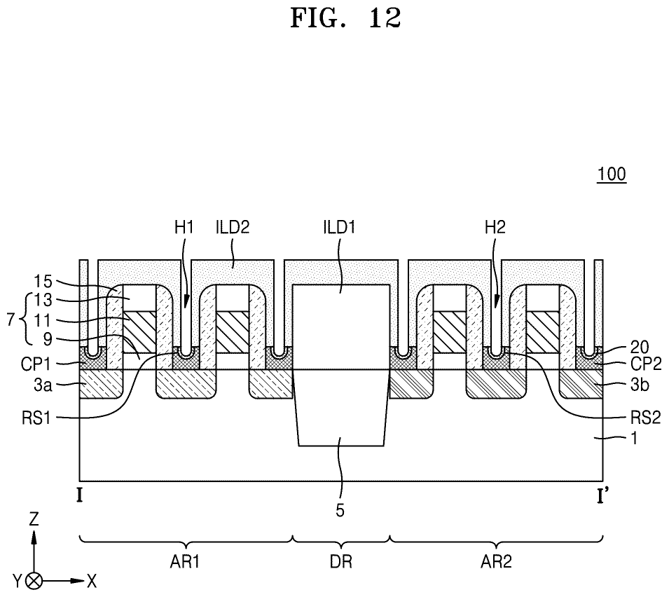

Referring to FIG. 12, the third hard mask HM3 may be removed, and the metal silicide layer 20 may be formed on the first contact pad CP1 and the second contact pad CP2. The metal silicide layer 20 may be arranged in the first recess RS1 and the second recess RS2. The forming of the metal silicide layer 20 may include depositing cobalt, nickel, or manganese in the first recess RS1 and the second recess RS2, additionally depositing titanium nitride, and performing annealing on the cobalt, nickel, or manganese and the titanium nitride. The metal silicide layer 20 may include or may be formed of cobalt silicide, nickel silicide, manganese silicide, or the like.

When the metal silicide layer 20 is directly formed on the first impurity region 3a and the second impurity region 3b, a defect in which the metal silicide layer 20 penetrates the substrate 1 may occur. When the metal silicide layer 20 penetrates the substrate 1, a leakage current may occur in sources/drains. Accordingly, the reliability of the integrated circuit device 100 (refer to 2) may be reduced.

According to the present disclosure, the metal silicide layer 20 may be formed on the first contact pad CP1 and the second contact pad CP2. Accordingly, the metal silicide layer 20 may not penetrate the substrate 1. Accordingly, because the leakage current described above may be prevented from occurring, the reliability of the integrated circuit device 100 (refer to FIG. 2) may be improved.

Referring to FIG. 2, the contact via 30 filling the first hole H1 and the second hole H2 may be formed. The forming of the contact via 30 may include forming a first conductive film (not shown) covering inner walls and bottom surfaces of the first hole H1 and the second hole H2, forming a second conductive film (not shown) on the first conductive film, and performing a planarization process on the first conductive film and the second conductive film. The planarization process may include a CMP process.

Then, the upper line 40 may be formed on the contact via 30. The line insulating film 50 covering the upper line 40 may be formed. Accordingly, the integrated circuit device 100 may be manufactured.

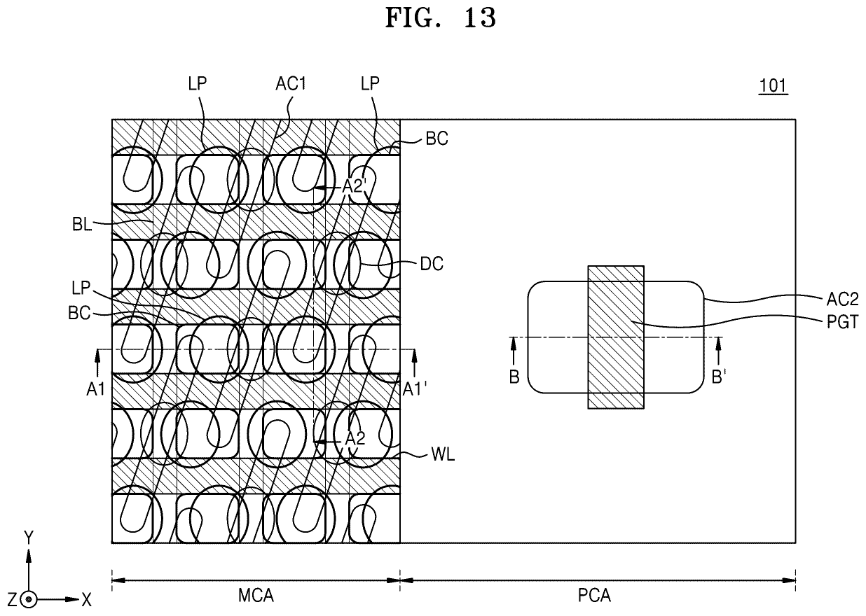

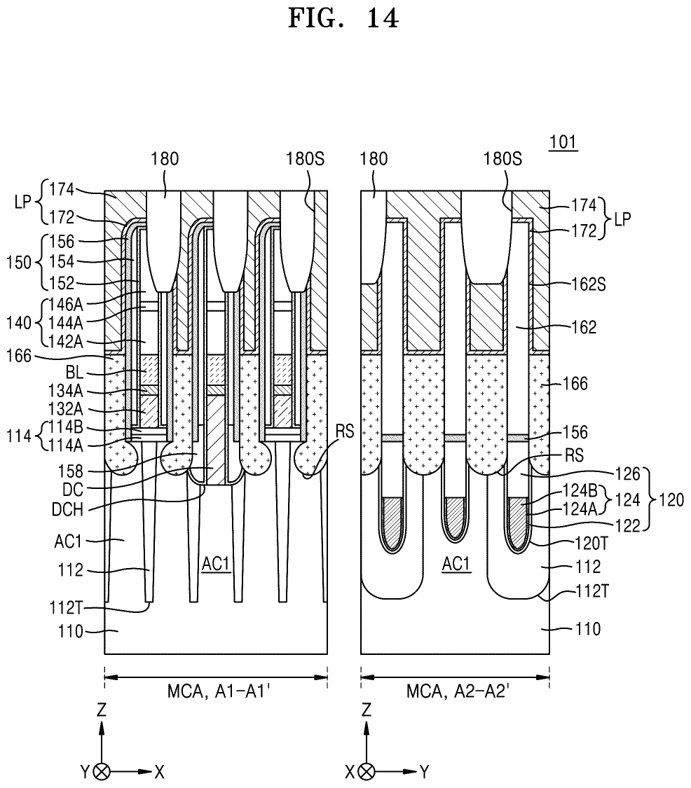

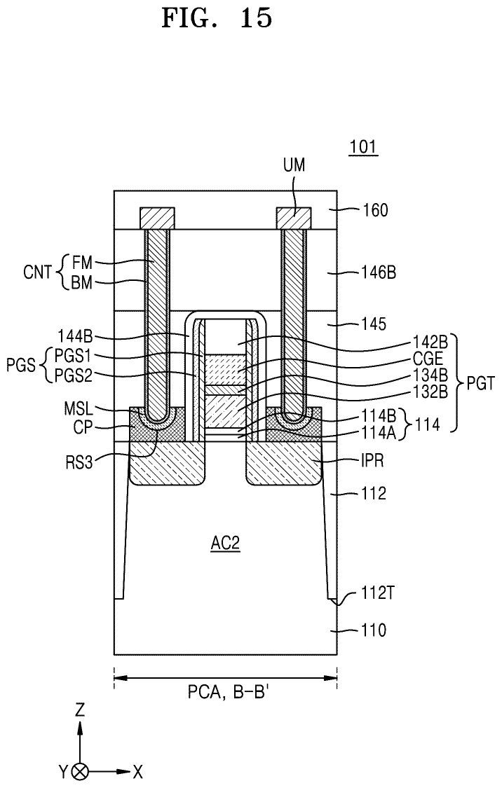

FIG. 13 is a layout diagram showing an integrated circuit device according to embodiments. FIG. 14 shows cross-sectional views of the integrated circuit device respectively taken along lines A1-A1′ and A2-A2′ of FIG. 13. FIG. 15 is a cross-sectional view of the integrated circuit device taken along a line B-B′ of FIG. 13.

Referring to FIGS. 13 to 15, an integrated circuit device 101 may include a substrate 110 including a cell array area MCA and a core-peripheral area PCA. A device isolation trench 112T may be formed in the substrate 110, and a device isolation film 112 may be formed in the device isolation trench 112T. A plurality of first active areas AC1 may be defined in the substrate 110 in the cell array area MCA by the device isolation film 112, and a second active area AC2 may be defined in the substrate 110 in the core-peripheral area PCA.

The plurality of first active areas AC1 in the cell array area MCA of the substrate 110 may each be arranged to have a long axis in a diagonal direction with respect to the first horizontal direction X and the second horizontal direction Y. In the cell array area MCA of the substrate 110, a plurality of word lines WL may cross the plurality of first active areas AC1 and extend in parallel to each other in the first horizontal direction X. On the plurality of word lines WL, a plurality of bit lines BL may extend in parallel to each other in the second horizontal direction Y. The plurality of bit lines BL may be arranged in the cell array area MCA. The plurality of bit lines BL may be connected to the plurality of first active areas AC1 through direct contacts DC.

Herein, in FIGS. 13 to 15, the first horizontal direction X may be defined as one direction parallel to an upper surface of the substrate 110, the second horizontal direction Y may be defined as one direction crossing the first horizontal direction X and parallel to the upper surface of the substrate 110, and the vertical direction Z may be defined as a direction perpendicular to the upper surface of the substrate 110.

A plurality of buried contacts BC may be formed between two bit lines BL adjacent to each other among the plurality of bit lines BL. The plurality of buried contacts BC may be arranged in a row in the first horizontal direction X and the second horizontal direction Y. A plurality of landing pads LP may be formed on the plurality of buried contacts BC. The plurality of buried contacts BC and the plurality of landing pads LP may connect a lower electrode (not shown) of a capacitor formed on an upper portion of the plurality of bit lines BL to the first active area AC1. The plurality of landing pads LP may each be arranged to partially overlap the buried contact BC.

The substrate 110 may include or may be formed of silicon, for example, single crystalline silicon, polycrystalline silicon, or amorphous silicon. In some other embodiments, the substrate 110 may include or may be formed of at least one selected from germanium, silicon germanium, SiC, gallium arsenide (GaAs), indium arsenide (InAs), and indium phosphorus (InP). In some embodiments, the substrate 110 may include a conductive area, for example, a well doped with an impurity, or a structure doped with an impurity. The device isolation film 112 may include or may be an oxide film, a nitride film, or a combination thereof.

In the cell array area MCA, a plurality of word line trenches 120T extending in the first horizontal direction X may be formed in the substrate 110, and a plurality of buried gate structures 120 may be arranged in the plurality of word line trenches 120T. Each of the plurality of buried gate structures 120 may include a gate dielectric film 122, a buried gate electrode 124, and a capping insulating film 126. The buried gate electrodes 124 included in the plurality of buried gate structures 120 may correspond to the plurality of word lines WL illustrated in FIG. 13. The gate dielectric film 122 may surround the buried gate electrode 124 and the capping insulating film 126. The capping insulating film 126 may be arranged on the buried gate electrode 124. The gate dielectric film 122 may include or may be a silicon oxide film, a silicon nitride film, a silicon oxynitride film, an oxide/nitride/oxide (ONO) film, or a high-k dielectric film having a higher dielectric constant than a silicon oxide film. The buried gate electrode 124 may include a work function adjustment layer 124A conformally arranged on a lower inner wall of each of the plurality of word line trenches 120T, and a buried conductive layer 124B filling the lower inner wall of each of the plurality of word line trenches 120T. For example, the work function adjustment layer 124A may include or may be formed of a metal, such as Ti, TiN, TiAlN, TiAlC, TiAlCN, TiSiCN, Ta, TaN, TaAlN, TaAlCN, TaSiCN, or the like, a metal nitride, or a metal carbide, and the buried conductive layer 124B may include or may be formed of at least one of W, WN, TiN, TaN, and doped polysilicon. The capping insulating film 126 may include or may be a silicon oxide film, a silicon nitride film, a silicon oxynitride film, or a combination thereof.

In the cell array area MCA and the core-peripheral area PCA, a buffer film 114 may be formed on the substrate 110. The buffer film 114 may include a first insulating film 114A and a second insulating film 114B. The first insulating film 114A and the second insulating film 114B may each include an oxide film, a nitride film, or a combination thereof. In the cell array area MCA, the buffer film 114 may be arranged between a lower conductive pattern 132A and the first active area AC1. In the core-peripheral area PCA, the buffer film 114 may be arranged between a lower conductive pattern 132B and the second active area AC2.

A plurality of direct contacts DC may be formed in a plurality of direct contact holes DCH in the substrate 110. The plurality of direct contacts DC may be connected to the plurality of first active areas AC1. The plurality of direct contacts DC may include or may be formed of doped polysilicon. For example, the plurality of direct contacts DC may each include polysilicon containing a relatively high concentration of N-type impurities such as phosphorus (P), arsenic (As), bismuth (Bi), and antimony (Sb).

The lower conductive pattern 132A, a middle conductive pattern 134A, and a bit line BL may be sequentially arranged on the substrate 110 and the plurality of direct contacts DC. A plurality of lower conductive patterns 132A, a plurality of middle conductive patterns 134A, and a plurality of bit lines BL may be provided. The plurality of lower conductive patterns 132A, the plurality of middle conductive patterns 134A, and the plurality of bit lines BL may extend long in the second horizontal direction Y. Each of the plurality of bit lines BL may be connected to the first active area AC1 through the middle conductive pattern 134A, the lower conductive pattern 132A, and the direct contact DC. The lower conductive pattern 132A may include or may be formed of doped polysilicon. The middle conductive pattern 134A and the bit line BL may each include titanium nitride, TiSiN, tungsten, tungsten silicide, or a combination thereof. In embodiments, the middle conductive pattern 134A may include or may be formed of titanium nitride, TiSiN, or a combination thereof, and the bit line BL may include or may be formed of a metal material such as tungsten.

The plurality of bit lines BL may be respectively covered with a plurality of insulating capping structures 140. Each of the plurality of insulating capping structures 140 may include a lower capping pattern 142A, an insulating layer pattern 144A, and an upper capping pattern 146A. Each of the lower capping pattern 142A, the insulating layer pattern 144A, and the upper capping pattern 146A may include or may be formed of a silicon nitride film. The plurality of insulating capping structures 140 may extend on the plurality of bit lines BL in the second horizontal direction Y.

A spacer structure 150 may be arranged on opposite sidewalls of each of the plurality of bit lines BL. The spacer structure 150 may extend on the opposite sidewalls of the plurality of bit lines BL in the second horizontal direction Y, and a portion of the spacer structure 150 may extend to the inside of the direct contact hole DCH to cover each of opposite sidewalls of the direct contact DC.

In embodiments, the spacer structure 150 may include a first spacer layer 152, a second spacer layer 154, and a third spacer layer 156. The first spacer layer 152 may be conformally arranged on sidewalls of the bit line BL, the middle conductive pattern 134A, and the lower conductive pattern 132A, a sidewall of the insulating capping structure 140, and an inner wall of the contact hole DCH. The second spacer layer 154 and the third spacer layer 156 may be sequentially arranged on the first spacer layer 152. In some embodiments, the first and third spacer layers 152 and 156 may each include silicon nitride, and the second spacer layer 154 may include or may be formed of silicon oxide. In some embodiments, the first and third spacer layers 152 and 156 may each include silicon nitride, and the second spacer layer 154 may include air or a low-k dielectric material. Here, the term “air” may mean the atmosphere or a space containing other gases that may exist during a manufacturing process.

A buried insulating layer 158 may surround a lower sidewall of the direct contact DC on the first spacer layer 152 and fill a remaining space of the direct contact hole DCH. The buried insulating layer 158 may include or may be formed of silicon nitride, silicon oxynitride, silicon oxide, or a combination thereof.

The direct contact DC may be formed in the direct contact hole DCH formed in the substrate 110 and may extend to a level higher than that of the upper surface of the substrate 110. For example, the upper surface of the direct contact DC may be arranged at the same level as the upper surface of the lower conductive pattern 132A, and the upper surface of the direct contact DC may be in contact with a bottom surface of the middle conductive pattern 134A. Also, the bottom surface of the direct contact DC may be arranged at a lower level than that of the upper surface of the substrate 110.

A plurality of insulating fences 162 and a plurality of conductive plugs 166 may be arranged between each of the plurality of bit lines BL in a row in the second horizontal direction Y. The plurality of insulating fences 162 may be arranged above the capping insulating film 126 arranged on an upper side of the plurality of word line trenches 120T, and may have an upper surface arranged on the same level as an upper surface of the insulating capping structure 140. The plurality of conductive plugs 166 may extend long in the vertical direction Z from a recess space RS formed in the substrate 110. Opposite sidewalls of each of the plurality of conductive plugs 166 in the second horizontal direction Y may be insulated from each other by the plurality of insulating fences 162. The plurality of insulating fences 162 may each include a silicon nitride film. The plurality of conductive plugs 166 may configure the plurality of buried contacts BC illustrated in FIG. 13.

The plurality of landing pads LP may be formed on the plurality of conductive plugs 166. The landing pad LP may be arranged to vertically overlap the conductive plug 166. The plurality of landing pads LP may be connected to the conductive plug 166. Although not illustrated in the drawings, a metal silicide film (not shown) may be arranged between the conductive plug 166 and the landing pad LP. The metal silicide film may include or may be formed of cobalt silicide, nickel silicide, manganese silicide, or the like.

The plurality of landing pads LP may cover a sidewall and an upper surface of the insulating capping structure 140 to vertically overlap some of the plurality of bit lines BL.

Each of the plurality of landing pads LP may include a conductive barrier pattern 172 and a landing pad conductive layer 174. The conductive barrier pattern 172 may include or may be formed of titanium, titanium nitride, or a combination thereof. The landing pad conductive layer 174 may include or may be formed of metal, metal nitride, conductive polysilicon, or a combination thereof. For example, the landing pad conductive layer 174 may include tungsten. The plurality of landing pads LP may have a plurality of island-shaped pattern shapes when viewed in a plan view.

The plurality of landing pads LP may be electrically insulated from each other by an insulating pattern 180 filling an insulating space 180S around the plurality of landing pads LP. The insulating pattern 180 may fill the insulating space 180S arranged between the bit line BL and the conductive plug 166 and may cover opposite sidewalls of the insulating capping structure 140.

In some embodiments, the insulating pattern 180 may include or may be formed of silicon nitride, silicon oxynitride, silicon oxide, or a combination thereof. In some embodiments, the insulating pattern 180 may be formed in a two-layered structure of a first material layer (not shown) and a second material layer (not shown), wherein the first material may include a low-k material such as SiO₂, SiOCH, and SiOC, and the second material layer may include silicon nitride or silicon oxynitride.

In the core-peripheral area PCA, a peripheral circuit gate structure PGT may be arranged on the second active area AC2. The peripheral circuit gate structure PGT may include the buffer film 114, the lower conductive pattern 132B, a middle conductive pattern 134B, an electrode pattern CGE, and a gate capping pattern 142B, which are sequentially stacked on the second active area AC2.

The buffer film 114 of the peripheral circuit gate structure PGT may include the first insulating film 114A and the second insulating film 114B. The first insulating film 114A in the core-peripheral area PCA may include or may be formed of the same material as the first insulating film 114A in the cell array area MCA. The second insulating film 114B in the core-peripheral area PCA may include or may be formed of the same material as the second insulating film 114B in the cell array area MCA. The buffer film 114 may correspond to the gate insulating layer 9 shown in FIG. 2. In the core-peripheral area PCA, the lower conductive pattern 132B, the middle conductive pattern 134B, and the electrode pattern CGE may be sequentially stacked on the buffer film 114. Constituent materials of the lower conductive pattern 132B, the middle conductive pattern 134B, and the electrode pattern CGE may be respectively the same as constituent materials of the lower conductive pattern 132A, the middle conductive pattern 134A, and bit line BL in the cell array area MCA. A combined configuration of the lower conductive pattern 132B, the middle conductive pattern 134B, and the electrode pattern CGE may correspond to the gate electrode 11 of FIG. 2. A constituent material of the gate capping pattern 142B may be the same as a constituent material of the lower capping pattern 142A in the cell array area MCA. The gate capping pattern 142B may correspond to the gate capping layer 13 of FIG. 2. The gate capping pattern 142B may include or may be formed of a silicon nitride film.

Each of opposite sidewalls of the peripheral circuit gate structure PGT may be covered with an insulating spacer PGS. The insulating spacer PGS may include a first insulating spacer PGS1, a second insulating spacer PGS2, and a third insulating spacer 144B, which are sequentially arranged on each of opposite sidewalls of the peripheral circuit gate structure PGT. The first insulating spacer PGS1 may directly cover each of the opposite sidewalls of the peripheral circuit gate structure PGT. The second insulating spacer PGS2 may cover an outer wall of the first insulating spacer PGS1. The third insulating spacer 144B may cover side and upper surfaces of the second insulating spacer PGS2 and an upper surface of the gate capping pattern 142B. Although not illustrated in the drawings, the third insulating spacer 144B may not cover the upper surface of the gate capping pattern 142B. The insulating spacer PGS may correspond to the gate spacer 15 of FIG. 2. Each of the first insulating spacer PGS1, the second insulating spacer PGS2, and the third insulating spacer 144B may include or may be formed of an oxide film, a nitride film, or a combination thereof. For example, the first insulating spacer PGS1 and the third insulating spacer 144B may include or may be formed of the same material, and the second insulating spacer PGS2 may include or may be formed of a different material from that of the first and third insulating spacers PGS1 and 144B. For example, the first insulating spacer PGS1 and the third insulating spacer 144B may include or may be formed of silicon nitride, and the second insulating spacer PGS2 may include or may be formed of silicon oxide. A constituent material of the third insulating spacer 144B may be the same as a constituent material of the insulating layer pattern 144A in the cell array area MCA.

An impurity region IPR may be arranged on each of opposite sides of the peripheral circuit gate structure PGT. The impurity region IPR may include an N-type impurity or a P-type impurity. The impurity region IPR may serve as a source/drain region of a transistor. The impurity region IPR may correspond to the first and second impurity regions 3a and 3b of FIG. 2. A portion of the impurity region IPR may vertically overlap the insulating spacer PGS.

A contact pad CP may be formed on the impurity region IPR. The contact pad CP may be connected to the impurity region IPR. A vertical level of a lower surface of the contact pad CP may be the same as a vertical level of an upper surface of the substrate 110. A vertical level of an upper surface of the contact pad CP may be lower than a vertical level of an upper surface of the peripheral circuit gate structure PGT. The contact pad CP may be in contact with the insulating spacer PGS. The contact pad CP may include a third recess RS3 at an upper surface of the contact pad CP. For example, the third recess RS3 may be dug downward in the vertical direction Z from the upper surface of the contact pad CP. In an embodiment, the third recess RS3 may be recessed from the upper surface of the contact pad CP toward the upper surface of the substrate 1 in the vertical direction Z. An impurity concentration of the contact pad CP may be greater than an impurity concentration of the impurity region IPR. For example, the impurity concentration of the contact pad CP may be greater than the impurity concentration of the impurity region IPR by 10 times or more. For example, the impurity concentration of the impurity region IPR may be about 1×10¹⁴ atoms/cm³ to about 1×10¹⁶ atoms/cm³, and the impurity concentration of the contact pad CP may be about 1×10¹⁵ atoms/cm³ to about 1×10²² atoms/cm³. The contact pad CP may correspond to the first contact pad CP1 and the second contact pad CP2 of FIG. 2. The third recess RS3 may correspond to the first recess RS1 and the second recess RS2 of FIG. 3A.

The contact pad CP may be selectively formed only in a particular transistor in the core-peripheral area PCA. That is, the contact pad CP may be formed on any one impurity region IPR, and conversely, the contact pad CP may also be omitted on the other impurity region IPR. When the contact pad CP is omitted, a contact via CNT may be directly connected to the other impurity region IPR.

A metal silicide layer MSL may be arranged on the contact pad CP. The metal silicide layer MSL may cover a surface of the third recess RS3. The metal silicide layer MSL may surround a lower portion of the contact via CNT. The metal silicide layer MSL may extend in the second horizontal direction Y. The metal silicide layer MSL may correspond to the metal silicide layer 20 of FIG. 2.

An interlayer insulating film 145 may be arranged to cover at least a portion of the third insulating spacer 144B. An upper surface of the interlayer insulating film 145 may have the same vertical level as an uppermost surface of the third insulating spacer 144B. The interlayer insulating film 145 may not cover the uppermost surface of the third insulating spacer 144B. The interlayer insulating film 145 may cover at least a portion of an upper surface and side surfaces of the contact pad CP. The interlayer insulating film 145 may cover an upper surface of the device isolation film 112. The interlayer insulating film 145 may include or may be formed of tonen silazene (TOSZ), but is not limited thereto.

An upper insulating film 146B may be arranged on the third insulating spacer 144B and the interlayer insulating film 145. A constituent material of the upper insulating film 146B may be the same as a constituent material of the upper capping pattern 146A.

The contact via CNT may be arranged to penetrate the interlayer insulating film 145 and the upper insulating film 146B. The contact via CNT may be connected to the metal silicide layer MSL. The contact via CNT may be spaced apart from the substrate 110 in the vertical direction Z. The contact via CNT may be spaced apart from the impurity region IPR in the vertical direction Z. The contact via CNT may not be directly connected to the impurity region IPR. The contact via CNT may include a third conductive pattern FM and a fourth conductive pattern BM. The contact via CNT may correspond to the contact via 30 of FIG. 2. The third conductive pattern FM may correspond to the first conductive pattern 31 of FIG. 2. The fourth conductive pattern BM may correspond to the second conductive pattern 33 of FIG. 2. Cross-sectional shapes of the contact pad CP, the metal silicide layer MSL, and the contact via CNT may respectively be the same as the cross-sectional shapes of the first and second contact pads CP1 and CP2, the metal silicide layer 20, and the contact via 30 described above with reference to FIGS. 3A to 3C.

An upper line UM may be arranged above the contact pad CP. The upper line UM may be connected to the contact pad CP. The upper line UM may extend in the first horizontal direction X or the second horizontal direction Y. The upper line UM may correspond to the upper line 40 of FIG. 2.

A line insulating film 160 may be arranged on the upper insulating film 146B. The line insulating film 160 may cover the upper insulating film 146B and the upper line UM. The line insulating film 160 may correspond to the line insulating film 50 of FIG. 2.

While the present disclosure has been particularly shown and described with reference to embodiments thereof, it will be understood that various changes in form and details may be made therein without departing from the spirit and scope of the following claims.

What is claimed is:

1. An integrated circuit device comprising:
a plurality of gate structures arranged on an upper surface of a substrate, wherein each of the plurality of gate structures includes a gate insulating film, a gate electrode, and a gate capping layer;
a first impurity region arranged at the upper surface of the substrate, wherein the first impurity region is adjacent to a first gate structure of the plurality of gate structures;
a first contact pad arranged on the upper surface of the substrate, wherein the first contact pad comprises a recess recessed in a vertical direction perpendicular to the upper surface of the substrate from an upper surface of the first contact pad toward the upper surface of the substrate;
a metal silicide layer disposed in the recess; and
a contact via connected to the metal silicide layer and extending in the vertical direction,
wherein a lower end of the contact via is disposed in the recess and connected to the metal silicide layer, and
wherein the contact via is spaced apart from the substrate in the vertical direction.

2. The integrated circuit device of claim 1,
wherein the first contact pad comprises an impurity of a same conductivity type as an impurity included in the first impurity region, and
an impurity concentration of the impurity in the first contact pad is greater than an impurity concentration of the impurity in the first impurity region.

3. The integrated circuit device of claim 1,
wherein the first contact pad comprises an impurity of a same conductivity type as an impurity included in the first impurity region,
wherein an impurity concentration of the impurity of the first contact pad is at least 10 times greater than an impurity concentration of the impurity of the first impurity region, and
wherein the impurity concentration of the impurity of the first impurity region is a value selected from a range of about 1×10¹⁴ atoms/cm³ to about 1×10¹⁶ atoms/cm³, and the impurity concentration of the impurity of the first contact pad is a value selected from a range of about 1×10¹⁵ atoms/cm³ to about 1×10²² atoms/cm³.

4. The integrated circuit device of claim 1,
wherein a lowermost surface of the contact via is lower than the upper surface of the first contact pad in the vertical direction.

5. The integrated circuit device of claim 4,
wherein the lowermost surface of the contact via is higher than a lower surface of the first contact pad in the vertical direction.

6. The integrated circuit device of claim 1,
wherein, when viewed in a plan view, the first contact pad overlaps the first impurity region.

7. The integrated circuit device of claim 1,
wherein, when viewed in a plan view, the contact via overlaps the first contact pad.

8. The integrated circuit device of claim 7,
wherein a width of the first contact pad in a horizontal direction parallel to the upper surface of the substrate is greater than a width of the contact via in the horizontal direction by a value selected from a range of about 2 nm to about 15 nm.

9. The integrated circuit device of claim 1,
wherein a lowermost surface of the metal silicide layer is higher than a lower surface of the first contact pad in the vertical direction.

10. The integrated circuit device of claim 1, further comprising:
a second impurity region arranged at the upper surface of the substrate, wherein the second impurity region is spaced apart from the first impurity region and is adjacent to a second gate structure of the plurality of gate structures; and
a second contact pad disposed on the second impurity region,
wherein an impurity included in the first contact pad has a first conductivity type,
an impurity included in the second contact pad has a second conductivity type, and
the first conductivity type is different from the second conductivity type.

11. The integrated circuit device of claim 1,
wherein, when viewed in a cross-sectional view, the recess has a recessed rounded surface.

12. The integrated circuit device of claim 1,
wherein, when viewed in a cross-sectional view, the recess includes a flat bottom surface and a side surface extending from the flat bottom surface in the vertical direction.

13. An integrated circuit device comprising:
a substrate having a cell array area and a core-peripheral circuit area next to the cell array area, wherein the substrate comprises a first active area at the cell array area and a second active area at the core-peripheral circuit area;
a device isolation film defining the first active area and the second active area;
a plurality of bit lines disposed on the first active area and spaced apart from each other in a first horizontal direction parallel to an upper surface of the substrate, wherein each of the plurality of bit lines extends in a second horizontal direction parallel to the upper surface of the substrate and different from the first horizontal direction;
a conductive plug arranged in a space between two adjacent bit lines;
a landing pad disposed on the conductive plug;
a peripheral circuit gate structure disposed on the second active area;
an impurity region arranged at the second active area and adjacent to the peripheral circuit gate structure;
a contact pad arranged on the impurity region, wherein the contact pad comprises a recess formed at an upper surface of the contact pad and recessed in a vertical direction perpendicular to the upper surface of the substrate from the upper surface of the contact pad toward the upper surface of the substrate; and
a contact via connected to the contact pad and extending in the vertical direction,
wherein the contact via is spaced apart from the substrate in the vertical direction.

14. The integrated circuit device of claim 13,
wherein the contact pad comprises an impurity of a same conductivity type as an impurity included in the impurity region, and
an impurity concentration of the impurity in the contact pad is greater than an impurity concentration of the impurity in the impurity region.

15. The integrated circuit device of claim 13, further comprising:
a metal silicide layer disposed in the recess,
wherein the metal silicide layer surrounds a lower portion of the contact via.

16. The integrated circuit device of claim 15,
wherein the metal silicide layer extends in the second horizontal direction.

17. The integrated circuit device of claim 13,
wherein, when viewed in a plan view, the contact via overlaps the contact pad.

18. The integrated circuit device of claim 17,
wherein a width of the contact pad in the first horizontal direction is greater than a width of the contact via in the first horizontal direction by a value selected from a range of about 2 nm to about 15 nm.

19. An integrated circuit device comprising:
a substrate having a cell array area and a core-peripheral circuit area next to the cell array area, wherein the substrate comprises a first active area at the cell array area and a second active area at the core-peripheral circuit area;
a device isolation film defining the first active area and the second active area;
a plurality of buried gate structures buried in the cell array area of the substrate and extending in a first horizontal direction parallel to an upper surface of the substrate, wherein each of the plurality of buried gate structures comprises a buried gate electrode, a capping insulating film on the buried gate electrode, and a gate dielectric film surrounding the buried gate electrode and the capping insulating film;
a plurality of bit lines disposed on the first active area and spaced apart from each other in the first horizontal direction, wherein each of the plurality of bit lines extends in a second horizontal direction parallel to the upper surface of the substrate and different from the first horizontal direction;
a plurality of insulating capping structures respectively arranged on the plurality of bit lines;
a conductive plug arranged in a space between two adjacent bit lines of the plurality of bit lines;
a landing pad disposed on the conductive plug;
a peripheral circuit gate structure disposed on the second active area and comprising a buffer film, a lower conductive pattern, a middle conductive pattern, an electrode pattern, and a gate capping pattern, which are sequentially stacked on the second active area;
an insulating spacer covering a sidewall of the peripheral circuit gate structure;
an impurity region arranged at the second active area to be next to the peripheral circuit gate structure;
a contact pad arranged on the impurity region, wherein the contact pad comprises a recess recessed in a vertical direction perpendicular to the upper surface of the substrate from an upper surface of the contact pad toward the upper surface of the substrate; and
a contact via connected to the contact pad and extending in the vertical direction,
wherein the contact via is spaced apart from the substrate in the vertical direction,
wherein a lower surface of the contact pad is coplanar with the upper surface of the substrate, and
wherein the upper surface of the contact pad is lower than an upper surface of the peripheral circuit gate structure.

20. The integrated circuit device of claim 19,
wherein the contact pad comprises polycrystalline silicon.
